(19) United States
(12) Patent Application Publication
(10) Pub. No.: US 2025/0098147 A1
(43) Pub. Date: Mar. 20, 2025

(54) SEMICONDUCTOR DEVICE

(71) Applicant: Samsung Electronics Co., Ltd., Suwon-si (KR)

(72) Inventors: Sunghwan JANG, Suwon-si (KR); Wonhee CHOI, Suwon-si (KR); Jinbum KIM, Suwon-si (KR); Daejin NAM, Suwon-si (KR); Hyojin PARK, Suwon-si (KR); Sunguk JANG, Suwon-si (KR)

(73) Assignee: Samsung Electronics Co., Ltd., Suwon-si (KR)

(21) Appl. No.: 18/828,170

(22) Filed: Sep. 9, 2024

(30) Foreign Application Priority Data
Sep. 19, 2023 (KR) 10-2023-0125005

(51) Int. Cl. H10B 12/00

(52) U.S. Cl. CPC H10B 12/315; H10B 12/05

(57) ABSTRACT

A semiconductor device includes a substrate, a bit line extending in a first direction on the substrate, a first vertical channel pattern and a second vertical channel pattern on the bit line, a back gate electrode between the first vertical channel pattern and the second vertical channel pattern and extending in a second direction perpendicular to the first direction across the bit line, a first word line extending in the second direction from one side of the first vertical channel pattern, a second word line extending in the second direction from other side of the second vertical channel pattern, and a contact pattern connected to each of the first vertical channel pattern and the second vertical channel pattern. When viewed from a cross-sectional view, each of the first vertical channel pattern and the second vertical channel pattern have a trapezoidal shape with the long sides facing each other.

### CROSS-REFERENCE TO RELATED APPLICATION

This application is based on and claims priority under 35 U.S.C. § 119 to Korean Patent Application No. 10-2023-0125005, filed on Sep. 19, 2023, in the Korean Intellectual Property Office, the disclosure of which is incorporated by reference herein in its entirety.

### BACKGROUND

The inventive concepts relate to semiconductor devices, and more specifically, to semiconductor devices including vertical channel transistors (VCTs).

In order to satisfy excellent performance and economic feasibility, it is required to increase a degree of integration of integrated circuit devices. In particular, the degree of integration of a memory device is an important factor in determining the economic feasibility of a product. Because the degree of integration of a two-dimensional (2D) memory device is mainly determined according to an area occupied by a unit memory cell, the degree of integration is greatly affected by a level of fine pattern forming technology. However, because expensive equipment is required to form a fine pattern and the area of a chip die is limited, the degree of integration of the 2D memory device is increasing, but is still limited.

### SUMMARY

The inventive concepts provide a semiconductor device including a vertical channel transistor (VCT) having reduced process difficulty and improved electrical characteristics by forming the vertical channel pattern by using a selective epitaxial growth method.

The problems to be solved by the inventive concepts are not limited to the problems mentioned above, and other problems not mentioned will be clearly understood by those skilled in the art from the following description.

According to an aspect of the inventive concepts, there is provided a semiconductor device including a substrate, a bit line extending in a first direction on the substrate, a first vertical channel pattern and a second vertical channel pattern on the bit line, a back gate electrode between the first vertical channel pattern and the second vertical channel pattern and extending in a second direction perpendicular to the first direction across the bit line, a first word line extending in the second direction from one side of the first vertical channel pattern, a second word line extending in the second direction from other side of the second vertical channel pattern, and a contact pattern connected to each of the first vertical channel pattern and the second vertical channel pattern. When viewed from a cross-sectional view, each of the first vertical channel pattern and the second vertical channel pattern have a trapezoidal shape with the long sides facing each other.

According to another aspect of the inventive concepts, there is provided a substrate, a bit line extending in a first direction on the substrate, a pair of vertical channel patterns on the bit line, a back gate electrode between the pair of vertical channel patterns and extending in a second direction perpendicular to the first direction across the bit line, a pair of word lines outside the pair of vertical channel patterns and extending in the second direction, and contact patterns connected to each of the pair of vertical channel patterns. Each of the pair of vertical channel patterns is an epitaxially grown layer having a top facet at a topmost portion of an inclined sidewall and a bottom facet at a bottommost portion of an inclined sidewall.

According to another aspect of the inventive concepts, there is provided a semiconductor device including a substrate, a bit line extending in a first direction on the substrate, a first vertical channel pattern and a second vertical channel pattern on the bit line, a back gate electrode between the first and second vertical channel patterns and extending in a second direction perpendicular to the first direction across the bit line, a first word line extending in the second direction from one side of the first vertical channel pattern, a second word line extending in the second direction from other side of the second vertical channel pattern, a gate insulating pattern conformally between the first and second vertical channel patterns and the first and second word lines and on top surfaces of the first and second word lines, a contact pattern connected to each of the first vertical channel pattern and the second vertical channel pattern, and a data storage pattern connected to the contact pattern. When viewed from a cross-sectional view, each of the first vertical channel pattern and the second vertical channel pattern has a trapezoidal shape that is a mirror image symmetrical structure with respect to the back gate electrode.

### BRIEF DESCRIPTION OF THE DRAWINGS

Various Example embodiments will be more clearly understood from the following detailed description taken in conjunction with the accompanying drawings in which:

FIG. 1 is a layout diagram illustrating a semiconductor device according to various example embodiments;

FIG. 2 is a cross-sectional view taken along a line B-B′in FIG. 1;

FIG. 3 is an enlarged cross-sectional view of a part CC of FIG. 2;

FIG. 4 is a flowchart illustrating a method of manufacturing a semiconductor device, according to various example embodiments;

FIGS. 5A to 20B are diagrams sequentially illustrating a method of manufacturing a semiconductor device, according to various example embodiments; and

FIG. 21 is a configuration diagram illustrating a system including a semiconductor device according to various example embodiments.

### DETAILED DESCRIPTION OF THE DRAWINGS

Hereinafter, various example embodiments of the inventive concepts will be described in detail with reference to the attached drawings.

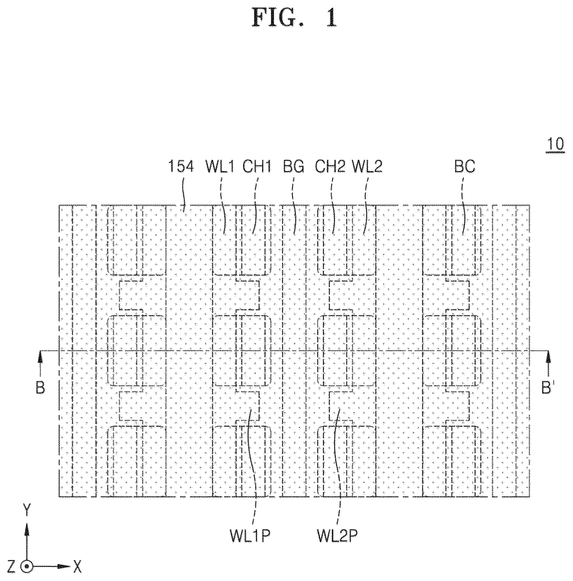

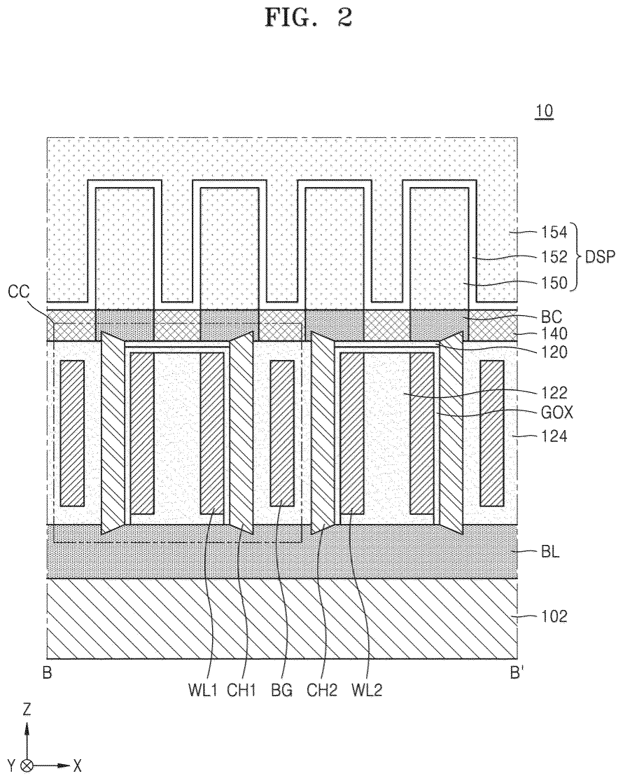

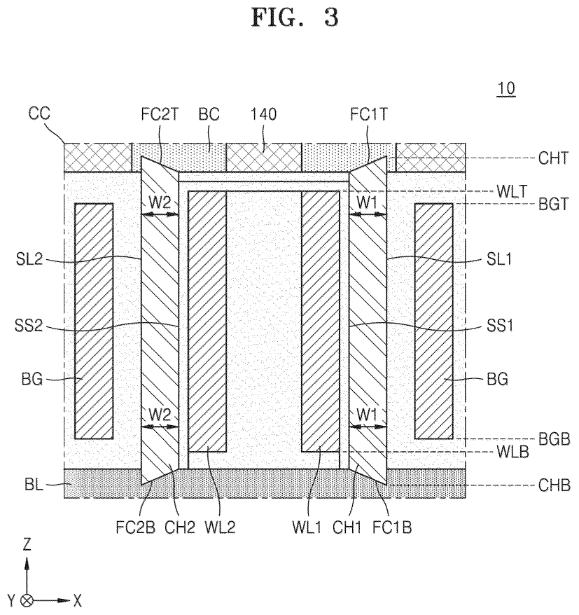

FIG. 1 is a layout diagram illustrating a semiconductor device 10 according to an embodiment. FIG. 2 is a cross-sectional view taken along a line B-B′ in FIG. 1. FIG. 3 is an enlarged cross-sectional view of a part CC of FIG. 2.

Referring to FIGS. 1 to 3 together, the semiconductor device 10 according to various example embodiments may include memory cells including a vertical channel transistor (VCT).

A substrate 102 may be one of a material (e.g., silicon and germanium) having semiconductor properties, an insulating material (e.g., glass and quartz), a semiconductor covered by the insulating material, or a conductor. Here, the substrate 102 may be a wafer including silicon (Si). In some example embodiments, the substrate 102 may be a wafer including a semiconductor element such as germanium (Ge), or a compound semiconductor such as silicon carbide (SiC), gallium arsenide (GaAs), indium arsenide (InAs), or indium phosphide (InP). Meanwhile, the substrate 102 may have a silicon on insulator (SOI) structure.

A bit line BL may extend in a first direction X on the substrate 102. A plurality of bit lines BLs may extend in the first direction X and may be spaced apart from each other in a second direction Y crossing the first direction X. The bit line BL may be configured as a conductive line. In some example embodiments, the bit line BL may include a conductive metal nitride (e.g., titanium nitride or tantalum nitride) or a metal (e.g., tungsten, titanium, or tantalum). Alternatively, the bit line BL may include a metal silicide, such as at least one of a titanium silicide, a cobalt silicide, or a nickel silicide. Alternatively, the bit line BL may include doped polysilicon.

A first vertical channel pattern CH1 and a second vertical channel pattern CH2 may be alternately disposed in the first direction X on the respective bit lines BL. In addition, the first and second vertical channel patterns CH1 and CH2 may be spaced apart from each other at a certain distance in the second direction Y. In other words, the first and second vertical channel patterns CH1 and CH2 may be two-dimensionally disposed in the first direction X and the second direction Y that cross each other.

Here, the first and second vertical channel patterns CH1 and CH2 may include a single crystal semiconductor material layer formed through a selective epitaxial growth method. In some example embodiments, the first and second vertical channel patterns CH1 and CH2 may each include single crystal silicon (Si). In some example embodiments, the first and second vertical channel patterns CH1 and CH2 may include doped silicon (Si) having a certain doping concentration in a certain conductivity type by adjusting a dopant and/or doping concentration during a selective epitaxial growth process.

Each of the first and second vertical channel patterns CH1 and CH2 may have a horizontal width in the first direction X, a horizontal length in the second direction Y, and a vertical length in a third direction Z perpendicular to the substrate 102. The first and second vertical channel patterns CH1 and CH2 may respectively have first and second horizontal widths W1 and W2 that are substantially uniform in the third direction Z except for the topmost and bottommost portions.

Each of the first and second vertical channel patterns CH1 and CH2 may have a trapezoidal shape. The first vertical channel pattern CH1 may have a first top facet FC1T located at a top portion of an inclined sidewall in the trapezoidal shape and a first bottom facet FC1B located at a bottom portion of the inclined sidewall in the trapezoidal shape. In addition, the second vertical channel pattern CH2 may have a second top facet FC2T located at a top portion of an inclined sidewall in the trapezoidal shape and a second bottom facet FC2B located at a bottom portion of the inclined sidewall in the trapezoidal shape. In addition, the first vertical channel pattern CH1 may have a first long side SL1 corresponding to a long side of a vertical sidewall in the trapezoidal shape and a first short side SS1 corresponding to a short side of the vertical sidewall in the trapezoidal shape. In addition, the second vertical channel pattern CH2 may have a second long side SL2 corresponding to a long side of a vertical sidewall in the trapezoidal shape and a second short side SS2 corresponding to a short side of the vertical sidewall in the trapezoidal shape.

In some example embodiments, the first bottom facet FC1B of the first vertical channel pattern CH1 and the second bottom facet FC2B of the second vertical channel pattern CH2 may each be buried in and contact the bit line BL. In addition, the first top facet FC1T of the first vertical channel pattern CH1 and the second top facet FC2T of the second vertical channel pattern CH2 may be respectively buried in and in contact with contact patterns BC. In some example embodiments, the first long side SL1 of the first vertical channel pattern CH1 may face a back gate electrode BG, and the second long side SL2 of the second vertical channel pattern CH2 may face another back gate electrode BG. In addition, the first short side SS1 of the first vertical channel pattern CH1 may face a first word line WL1, and the second short side SS2 of the second vertical channel pattern CH2 may face a second word line WL2.

The trapezoidal shape of each of the first and second vertical channel patterns CH1 and CH2 and an arrangement of components thereof accordingly may be due to the fact that the first and second vertical channel patterns CH1 and CH2 have each a crystal plane according to the selective epitaxial growth method.

The first and second word lines WL1 and WL2 may be alternately arranged in the first direction X on the bit line BL and extend in the second direction Y. The first word line WL1 may be disposed to face the first short side SSI that is one side of the first vertical channel pattern CH1 without facing the first top facet FC1T and the first bottom facet FC1B of the first vertical channel pattern CH1. In addition, the second word line WL2 may be disposed to face the second short side SS2 that is the other side of the second vertical channel pattern CH2 without facing the second top facet FC2T and the second bottom facet FC2B of the second vertical channel pattern CH2. Here, the first and second word lines WL1 and WL2 may be vertically spaced apart from the bit line BL and the contact pattern BC. In other words, when viewed from a plan view, the first and second word lines WL1 and WL2 may be located between the bit line BL and the contact pattern BC.

In some example embodiments, when viewed in a plan view, the first word line WL1 may have a plurality of first protrusions WL1P protruding in a direction in which the first vertical channel pattern CH1 is disposed, and the second word line WL2 may have a plurality of second protrusions WL2P protruding in a direction in which the second vertical channel pattern CH2 is disposed. According to such an arrangement, the first word line WL1 including the plurality of first protrusions WL1P and the second word line WL2 including the plurality of second protrusions WL2P may have a mirror image symmetric structure with respect to the back gate electrode BG.

In some example embodiments, when viewed in a plan view, the first word line WL1 including the plurality of first protrusions WL1P may be disposed to face the first vertical channel pattern CH1 on three different planes. That is, the first word line WL1 may form a tri-gate structure. Similarly, when viewed in a plan view, the second word line WL2 including the plurality of second protrusions WL2P may be disposed to face the second vertical channel pattern CH2 on three different planes. That is, the second word line WL2 may form a tri-gate structure.

The first and second word lines WL1 and WL2 may each include, for example, doped polysilicon, metal, conductive metal nitride, conductive metal silicide, conductive metal oxide, or a combination thereof. However, example embodiments are not limited thereto.

The first and second word lines WL1 and WL2 may each have a vertical length in the third direction Z that is less than a vertical length of each of the first and second vertical channel patterns CH1 and CH2. In addition, the first and second word lines WL1 and WL2 may each have a vertical length that is greater than the vertical length of the back gate electrode BG in the third direction Z. In other words, a topmost surface level CHT of each of the first and second vertical channel patterns CH1 and CH2 may be higher than a topmost surface level WLT of each of the first and second word lines WL1 and WL2, and a topmost surface level WLT of each of the first and second word lines WL1 and WL2 may be higher than a topmost surface level BGT of the back gate electrode BG. In addition, a bottommost level CHB of each of the first and second vertical channel patterns CH1 and CH2 may be lower than a bottommost level WLB of each of the first and second word lines WL1 and WL2, and a bottommost level WLB of each of the first and second word lines WL1 and WL2 may be lower than a bottommost level BGB of the back gate electrode BG.

A first insulating pattern 120 may be disposed between the first and second vertical channel patterns CH1 and CH2 that are adjacent to each other in the first direction X. The first insulating pattern 120 may be disposed adjacent to the first top facet FC1T and the second top facet FC2T of the first and second vertical channel patterns CH1 and CH2. A level of a top surface of each of the first and second word lines WL1 and WL2 may vary depending on a thickness of the first insulating pattern 120. The first insulating pattern 120 may include, for example, a silicon oxide layer, a silicon oxynitride layer, or a silicon nitride layer. However, example embodiments are not limited thereto.

A gate insulating pattern GOX may be disposed between the first and second word lines WL1 and WL2 and the first and second vertical channel patterns CH1 and CH2. The gate insulating pattern GOX may extend in the second direction Y parallel to the first and second word lines WL1 and WL2.

The gate insulating pattern GOX may contact the first short side SS1 of the first vertical channel pattern CH1 and the second short side SS2 of the second vertical channel pattern CH2. In addition, the gate insulating pattern GOX may contact the first insulating pattern 120. That is, the gate insulating pattern GOX may have a substantially uniform thickness and may be disposed to have an inverted U shape when viewed in a cross-sectional view.

The gate insulating pattern GOX may include a silicon oxide layer, a silicon oxynitride layer, a high-k dielectric layer having a higher dielectric constant than that of the silicon oxide layer, or a combination thereof. The high-k dielectric layer may include metal oxide or metal oxynitride. For example, the high-k dielectric layer that may be used as the gate insulating pattern GOX may include HfO₂, HfSiO, HfSiON, HfTaO, HfTIO, HfZrO, ZrO₂, Al₂O₃, or a combination thereof, but example embodiments are not limited thereto.

A second insulating pattern 122 may be disposed to fill between the gate insulating pattern GOX and the first and second word lines WL1 and WL2. That is, on the gate insulating pattern GOX, the first and second word lines WL1 and WL2 may be electrically separated from each other by the second insulating pattern 122. The second insulating pattern 122 may include, for example, a silicon oxide layer, a silicon oxynitride layer, or a silicon nitride layer. However, example embodiments are not limited thereto.

The back gate electrodes BG may be spaced apart from each other by a certain distance in the first direction X on the bit line BL. The back gate electrodes BG may extend in the second direction Y across the bit line BL. Each of the back gate electrodes BG may be disposed between the first and second vertical channel patterns CHI and CH2 that are adjacent to each other in the first direction X. In other words, the first vertical channel pattern CH1 may be disposed on one side of the back gate electrode BG, and the second vertical channel pattern CH2 may be disposed on the other side thereof.

The back gate electrode BG may include, for example, doped polysilicon, conductive metal nitride (e.g. titanium nitride and tantalum nitride), a metal (e.g. tungsten, titanium and tantalum), conductive metal silicide, conductive metal oxide, or a combination thereof. However, example embodiments are not limited thereto. A negative voltage may be applied to the back gate electrode BG when the semiconductor device 10 operates and may increase a threshold voltage of the VCT. That is, the back gate electrode BG may prevent leakage current characteristics from deteriorating due to a reduction in the threshold voltage as the VCT is miniaturized.

A back gate insulating pattern 124 may be disposed between the back gate electrode BG and the first and second vertical channel patterns CH1 and CH2. The back gate insulating pattern 124 may include vertical portions covering both sides of the back gate electrode BG and horizontal portions connecting the vertical portions. A level of each of top and bottom surfaces of the back gate electrode BG may vary depending on the thickness of the back gate insulating pattern 124. The back gate insulating pattern 124 may include, for example, a silicon oxide layer, a silicon oxynitride layer, or a silicon nitride layer. However, example embodiments are not limited thereto.

The contact patterns BC may penetrate an isolation insulating layer 140 and be respectively connected to the first and second vertical channel patterns CH1 and CH2. In other words, the contact patterns BC may be respectively connected to the first top facet FC1T and the second top facet FC2T of the first and second vertical channel patterns CH1 and CH2. The contact patterns BC that are adjacent to each other may be separated from each other by the isolation insulating layer 140. When viewed from a plan view, each of the contact patterns BC may have various shapes, such as circular, oval, rectangular, square, rhombic, or hexagonal shapes.

A data storage pattern DSP may be disposed on the contact pattern BC. The data storage pattern DSP may be electrically connected to each of the first and second vertical channel patterns CH1 and CH2. The data storage pattern DSP may be disposed in a matrix form in the first direction X and the second direction Y. The data storage pattern DSP may completely or partially overlap the contact pattern BC. The data storage pattern DSP may contact all or part of the top surface of the contact pattern BC.

In some example embodiments, the data storage pattern DSP may be a capacitor and may include a capacitor dielectric layer 152 disposed between a storage electrode 150 and a plate electrode 154. In this case, the storage electrode 150 may be in direct contact with the contact pattern BC, and when viewed from a plan view, the storage electrode 150 may have various shapes, such as circular, oval, rectangular, square, rhombic, or hexagonal shapes.

In contrast, the data storage pattern DSP may be a variable resistance pattern that may be switched between two resistance states by electrical pulses applied to a memory element. For example, the data storage pattern DSP may include a phase-change material whose crystal state changes depending on the amount of current, a perovskite compound, a transition metal oxide, a magnetic material, a ferromagnetic material, an antiferromagnetic material, etc., but example embodiments are not limited thereto.

Generally, the first and second vertical channel patterns CH1 and CH2 perform several dry etching processes to form a semiconductor material layer and form a vertical channel pattern only at a wanted position. In such dry etching process, there is a problem in that unwanted etch damage occurs in the first and second vertical channel patterns CH1 and CH2. In addition, even though an elaborate dry etching process is performed, some differences may occur in the horizontal width of each of the first and second vertical channel patterns CH1 and CH2, and it is difficult to control the concentration doping of each of the first and second vertical channel patterns CH1 and CH2.

In contrast, in the semiconductor device 10 according to the inventive concepts, in the process of forming memory cells including VCTs, the first and second vertical channel patterns CH1 and CH2 may be formed using a selective epitaxial growth method. As described above, formation process of the first and second vertical channel patterns CH1 and CH2 are different, and thus, etch damage that may occur during the dry etching process may be significantly reduced, and the horizontal widths of the first and second vertical channel patterns CH1 and CH2 may be significantly the same. In addition, in the selective epitaxial growth process of the first and second vertical channel patterns CH1 and CH2, the wanted doping concentration may be easily adjusted with the wanted dopant.

Ultimately, the semiconductor device 10 according to the inventive concepts may reduce process difficulty and improve electrical characteristics.

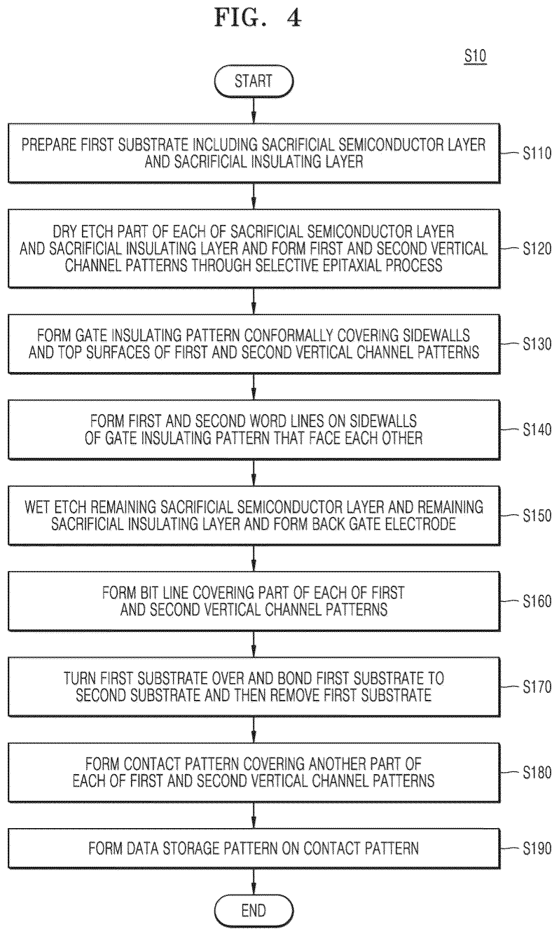

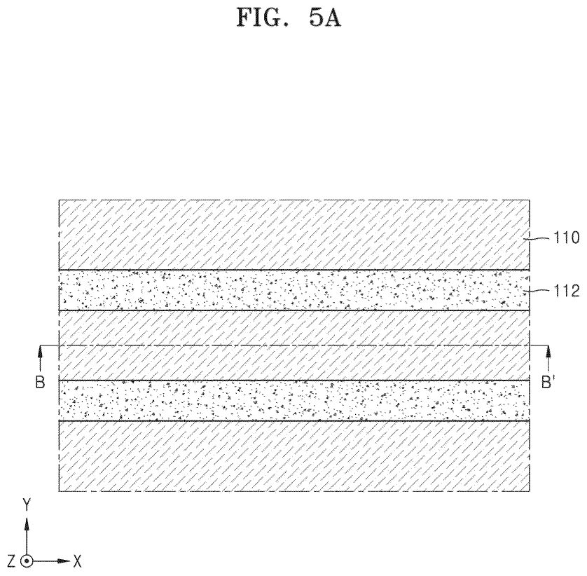

FIG. 4 is a flowchart illustrating a method of manufacturing a semiconductor device according to an embodiment.

In cases where an embodiment may be implemented differently, a specific process sequence may be performed differently from the described sequence. For example, two processes described in succession may be performed substantially at the same time or may be performed in an order opposite to the order described.

Referring to FIG. 4, the method (S10) of manufacturing the semiconductor device according to various example embodiments may include process sequences of first to ninth operations (S110 to S190).

The method (S10) of manufacturing the semiconductor device according to various example embodiments may include a first operation (S110) of preparing a first substrate including a sacrificial semiconductor layer and a sacrificial insulating layer, a second operation (S120) of dry etching a part of each of the sacrificial semiconductor layer and the sacrificial insulating layer and forming first and second vertical channel patterns through a selective epitaxial process, a third operation (S130) of forming a gate insulating pattern conformally covering sidewalls and top surfaces of the first and second vertical channel patterns, a fourth operation (S140) of forming first and second word lines on sidewalls of the gate insulating pattern that face each other, a fifth operation (S150) of wet etching the remaining sacrificial semiconductor layer and the remaining sacrificial insulating layer and forming a back gate electrode, a sixth operation (S160) of forming a bit line covering a part of each of the first and second vertical channel patterns, a seventh operation (S170) of turning the first substrate over and bonding the first substrate to a second substrate, and then removing the first substrate, an eighth operation (S180) of forming a contact pattern covering another part of each of the first and second vertical channel patterns, and a ninth operation (S190) of forming a data storage pattern on the contact pattern.

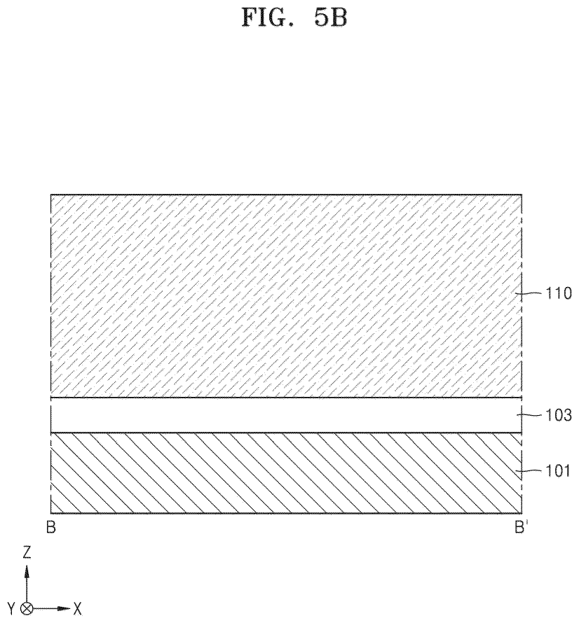

A technical feature of each of the first to ninth operations (S110 to S190) are described in detail with reference to FIGS. 5A to 20B below.

FIGS. 5A to 20B are diagrams sequentially illustrating a method of manufacturing the semiconductor device 10 according to an embodiment.

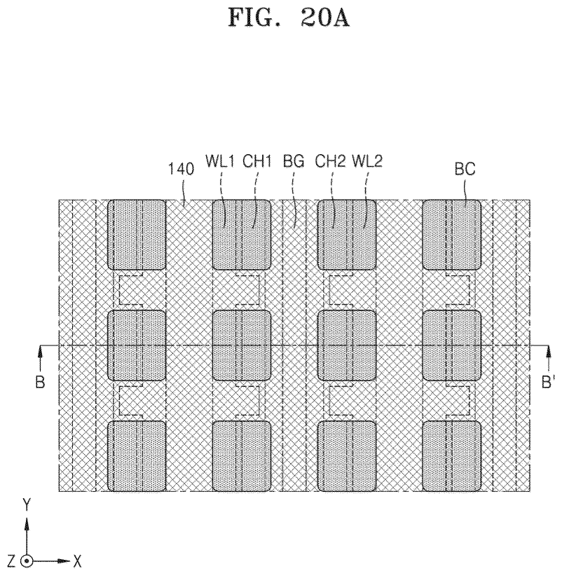

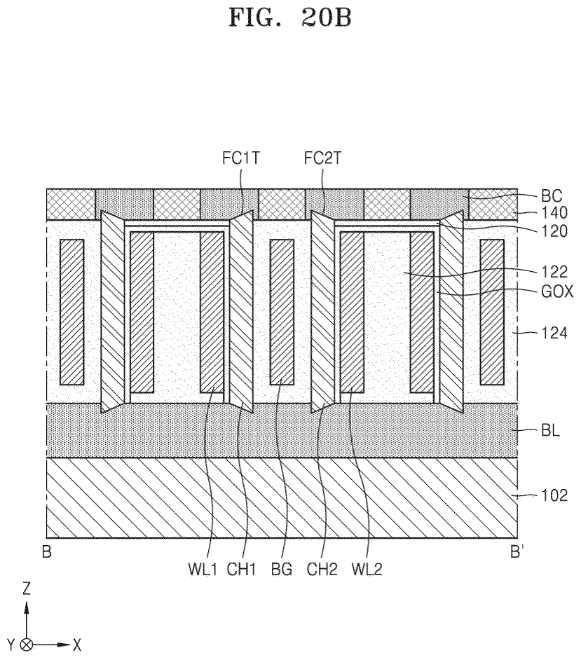

Specifically, FIGS. 5A, 6A, 7A, . . . , FIG. 20A are plan views illustrating the semiconductor device 10 according to various example embodiments. FIGS. 5B, 6B, 7B, . . . , FIG. 20B are respectively cross-sectional views taken along line B-B′in corresponding FIGS. 5A, 6A, 7A, . . . , FIG. 20A.

Referring to FIGS. 5A and 5B together, a first substrate 101 including a base insulating layer 103 and a sacrificial semiconductor layer 110 may be prepared.

The first substrate 101 may be a wafer including silicon (Si). Alternatively, the first substrate 101 includes a semiconductor element such as germanium (Ge) or a compound semiconductor such as silicon carbide (SiC), gallium arsenide (GaAs), indium arsenide (InAs), or indium phosphide (InP). However, example embodiments are not limited thereto. Additionally, the first substrate 101 may have a silicon on insulator (SOI) structure.

The base insulating layer 103 may be, for example, a buried oxide. Alternatively, the base insulating layer 103 may be an insulating layer formed by using a chemical vapor deposition method. The base insulating layer 103 may include, for example, silicon oxide, silicon nitride, silicon oxynitride, and/or a low dielectric material. However, example embodiments are not limited thereto. In some embodiments, the base insulating layer 103 may be omitted according to a type of the first substrate 101.

The sacrificial semiconductor layer 110 may be, for example, silicon germanium (SiGe). The sacrificial semiconductor layer 110 may have a top surface and a bottom surface which are opposite to each other, and the bottom surface may be in contact with the base insulating layer 103.

A sacrificial insulating layer 112 extending in the first direction X while cutting the sacrificial semiconductor layer 110 may be formed between the sacrificial semiconductor layers 110. The sacrificial insulating layer 112 may be formed on the sacrificial semiconductor layer 110 by using a photolithography process and an etching process, which is obvious to those skilled in the art, and thus, a detailed description thereof is omitted. By the sacrificial insulating layer 112, the sacrificial semiconductor layer 110 may be formed to extend longest in the first direction X and be spaced apart from each other in the second direction Y.

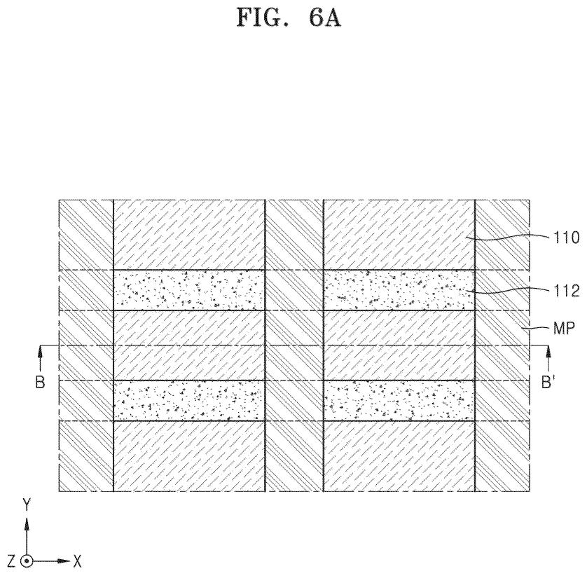

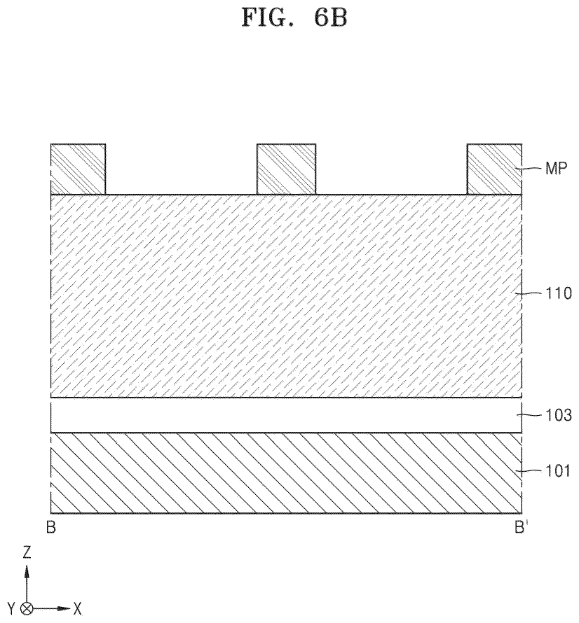

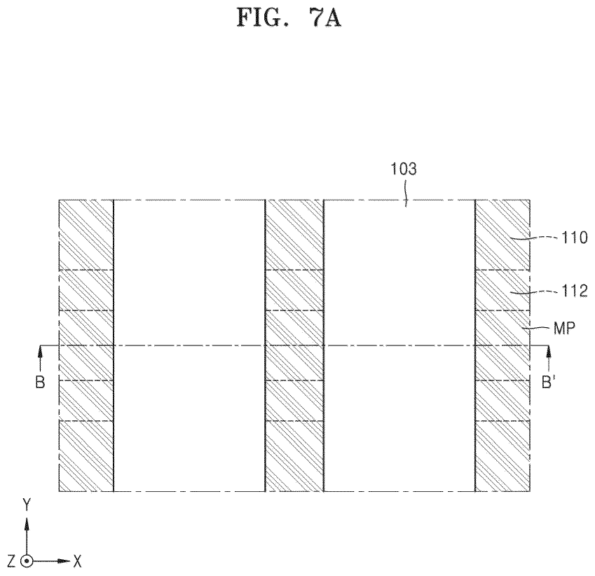

Referring to FIGS. 6A and 6B together, mask patterns MP may be formed on the sacrificial semiconductor layer 110 and the sacrificial insulating layer 112.

The mask patterns MP may be spaced apart from each other in the first direction X and may have a line shape extending long in the second direction Y. That is, the mask pattern MP may be formed in a line and space shape. In some example embodiments, the mask pattern MP may include a photoresist or a hardmask. Alternatively, the mask pattern MP may include, for example, a carbon-based material.

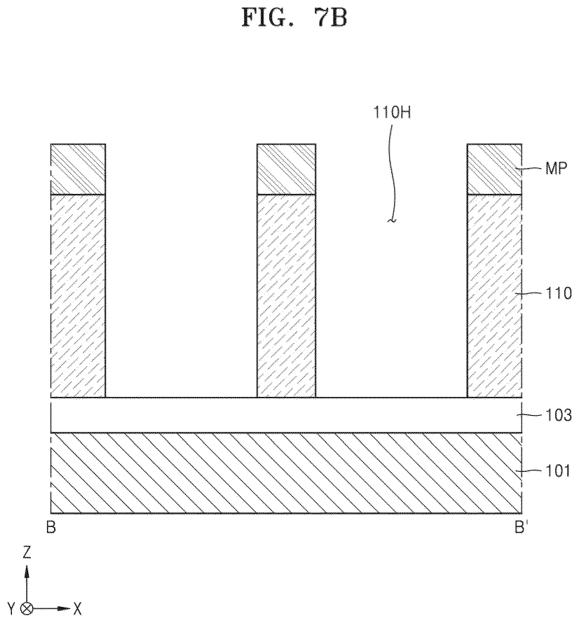

Referring to FIGS. 7A and 7B together, the sacrificial semiconductor layer 110 and the sacrificial insulating layer 112 may be anisotropically etched by using the mask pattern MP as an etch mask.

Anisotropic etching may be a dry etching process. Accordingly, first openings 110H extending in the second direction Y may be formed in the sacrificial semiconductor layer 110 and the sacrificial insulating layer 112. Through the first openings 110H, the top surface of the base insulating layer 103 may be exposed, and a sidewall of each of the sacrificial semiconductor layer 110 and the sacrificial insulating layer 112 may be exposed. The first openings 110H may be spaced apart from each other by a certain distance in the first direction X.

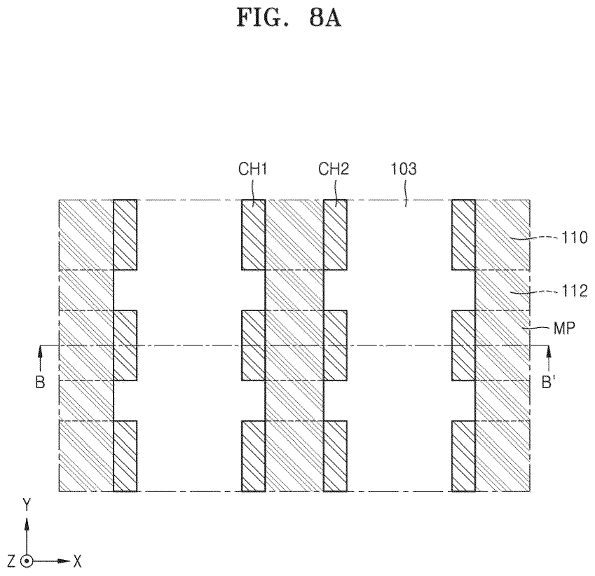

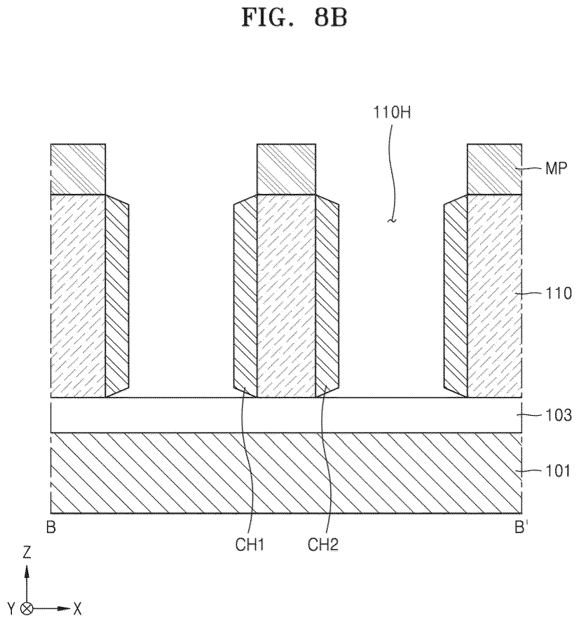

Referring to FIGS. 8A and 8B together, the first and second vertical channel patterns CH1 and CH2 may be formed on exposed surfaces of the sacrificial semiconductor layers 110.

The first and second vertical channel patterns CH1 and CH2 may each be a silicon (Si) epitaxial growth layer formed through a selective epitaxial growth process. In other words, the first and second vertical channel patterns CH1 and CH2 may be selectively grown only on the exposed surfaces of the sacrificial semiconductor layers 110. The epitaxial growth layer formed through the selective epitaxial growth process has a different growth rate according to a crystal plane, and thus, a profile of each of the first and second vertical channel patterns CH1 and CH2 may have a trapezoidal shape and form a facet.

In some example embodiments, the first and second vertical channel patterns CH1 and CH2 may be doped with boron (B), which is a p-type impurity, phosphorus (P), which is an n-type impurity, and thus may include doped silicon (Si). If necessary, the first and second vertical channel patterns CH1 and CH2 may be in-situ doped with impurities during the selective epitaxial growth.

Next, the mask pattern MP may be removed. In some example embodiments, the mask pattern MP may be removed through an ashing and stripping process.

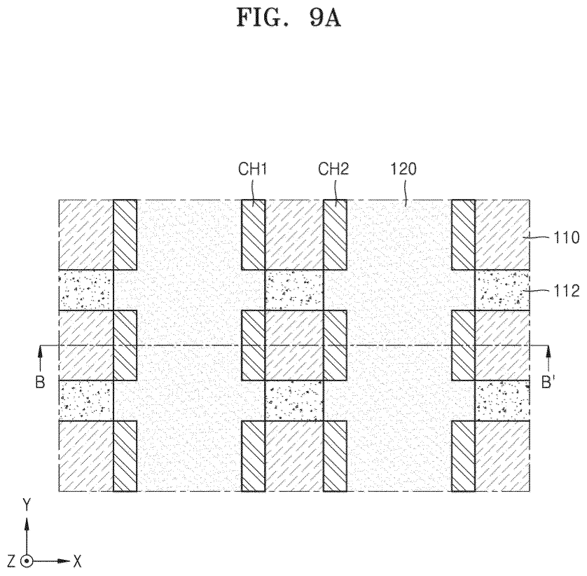

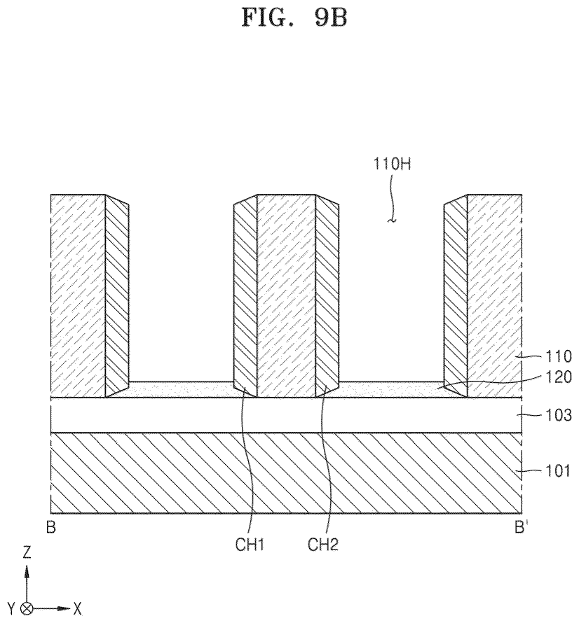

Referring to FIGS. 9A and 9B together, the first insulating pattern 120 may be formed on the top surface of the base insulating layer 103 exposed by the first opening 110H.

The first insulating pattern 120 may be formed by depositing an insulating material to completely fill the first opening 110H and then partially etching the insulating material by using an etching process. Accordingly, the first insulating pattern 120 may be formed to have a certain thickness only on the top surface of the base insulating layer 103.

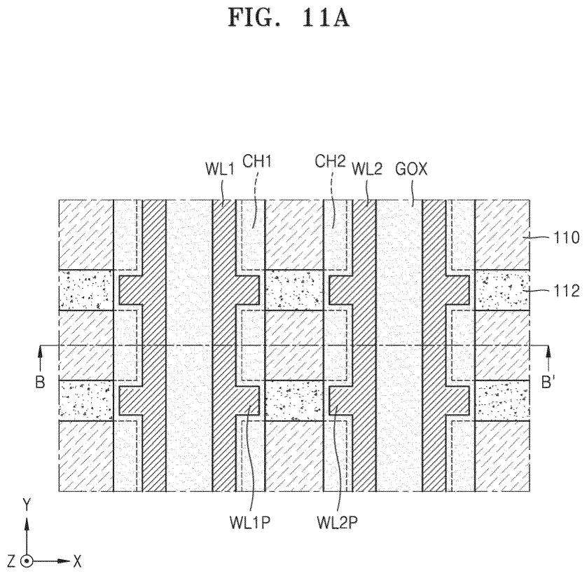

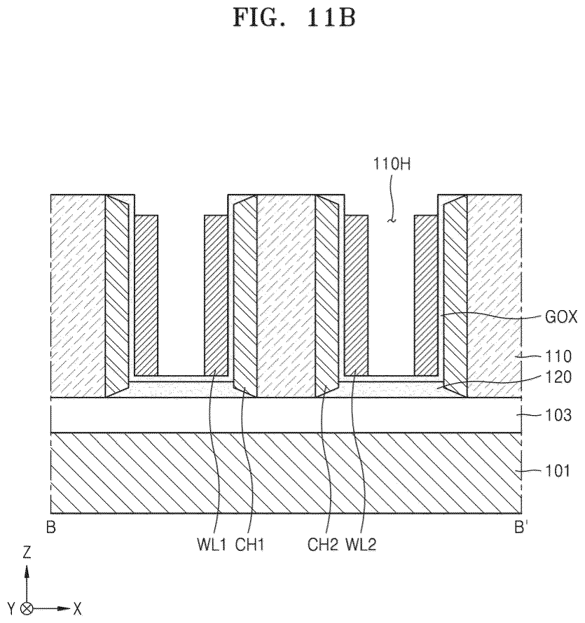

The first insulating pattern 120 may be used as an insulating pattern for height adjustment such that positions of the first and second word lines WL1 and WL2 (see FIG. 11B) described below in the third direction Z are determined. That is, vertical positions of the first and second word lines (WL1 and WL2 (see FIG. 11B) may be adjusted according to the thickness of the first insulating pattern 120. The first insulating pattern 120 may include, for example, a silicon oxide layer, a silicon oxynitride layer, or a silicon nitride layer. However, example embodiments are not limited thereto.

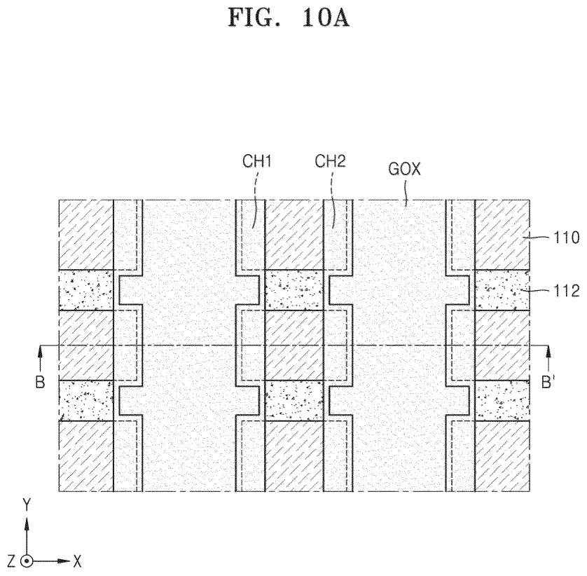

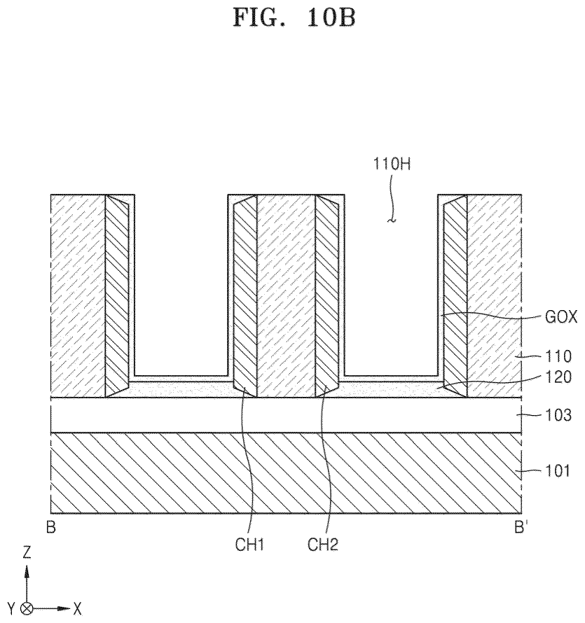

Referring to FIGS. 10A and 10B together, the gate insulating pattern GOX may be formed to conformally cover the top surface of the first insulating pattern 120, the sidewalls of the first and second vertical channel patterns CH1 and CH2, and top surfaces of the first and second vertical channel patterns CH1 and CH2 at uniform thicknesses.

Accordingly, in the first opening 110H, the gate insulating pattern GOX may be disposed to have a substantially uniform thickness in a required area and to have a U-shape when viewed in a cross-sectional view.

The gate insulating pattern GOX may include, for example, a silicon oxide layer, a silicon oxynitride layer, a high-k dielectric layer having a higher dielectric constant than the silicon oxide layer, or a combination thereof. However, example embodiments are not limited thereto. In some example embodiments, the high-k dielectric layer may include metal oxide or metal oxynitride. For example, the high-k dielectric layer that may be used as the gate insulating pattern GOX may include HfO₂, HfSiO, HfSiON, HfTaO, HfTIO, HfZrO, ZrO₂, Al₂O₃, or a combination thereof, but example embodiments are not limited thereto.

Referring to FIGS. 11A and 11B together, in the first opening 110H, the first and second word lines WL1 and WL2 may be formed to be spaced apart from each other on sidewalls of the gate insulating pattern GOX that face each other.

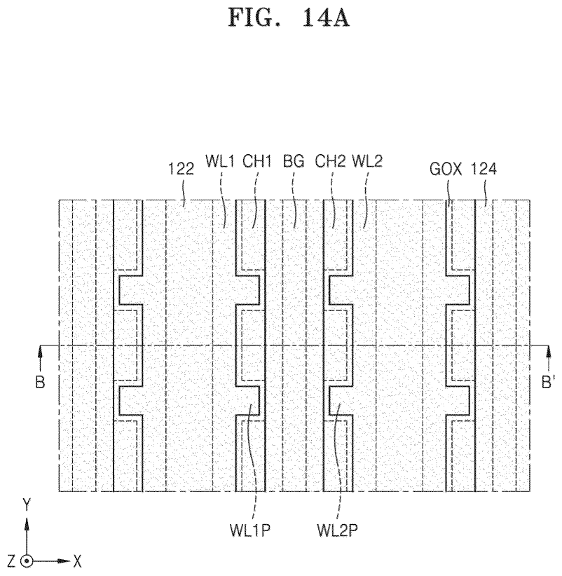

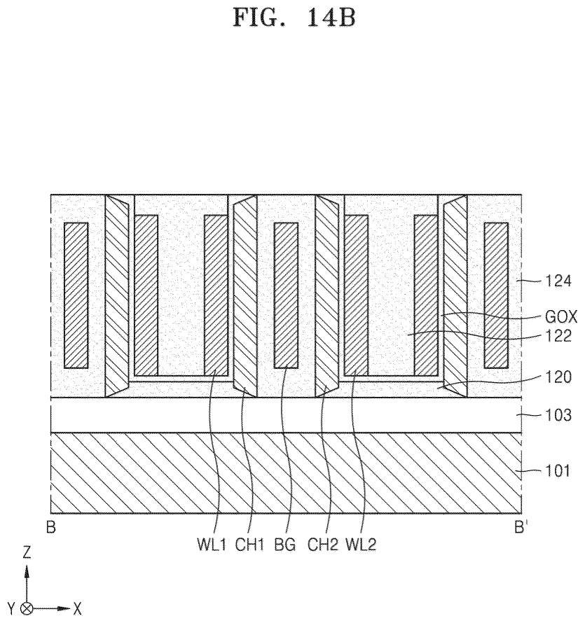

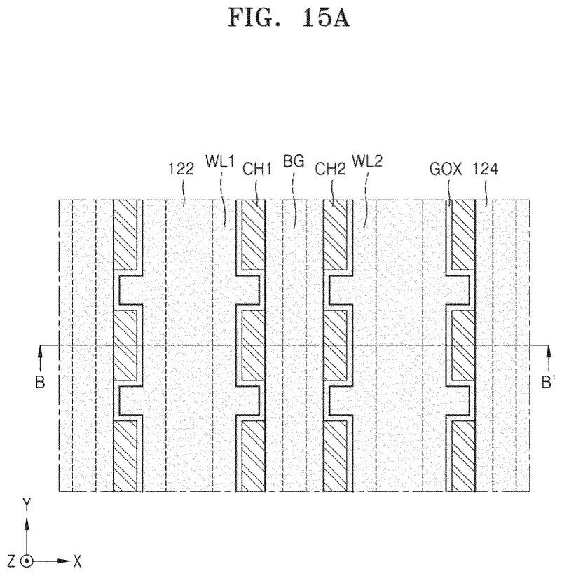

That is, according to the inventive concepts, the first and second word lines WL1 and WL2 may be formed before the back gate electrode BG (see FIG. 14B), which will be described below.

An operation of forming the first and second word lines WL1 and WL2 may include an operation of forming a gate conductive layer conformally covering the gate insulating pattern GOX and then performing an anisotropic etching process on the gate conductive layer. Here, a thickness of each of the first and second word lines WL1 and WL2 may be adjusted according to a thickness of the gate conductive layer. In addition, the top surfaces of the first and second word lines WL1 and WL2 may have various levels according to the anisotropic etching process on the gate conductive layer.

In some example embodiments, when viewed in a plan view, the first word line WL1 may have the plurality of first protrusions WL1P protruding between a plurality of first vertical channel patterns CH1, and the second word line WL2 may have the plurality of second protrusions WL2P protruding between a plurality of second vertical channel pattern CH2 is disposed.

In some embodiments, when viewed in a plan view, the first word line WL1 including the plurality of first protrusions WL1P may be disposed to face the first vertical channel pattern CH1 on three different planes. Similarly, when viewed in a plan view, the second word line WL2 including the plurality of second protrusions WL2P may be disposed to face the second vertical channel pattern CH2 on three different planes.

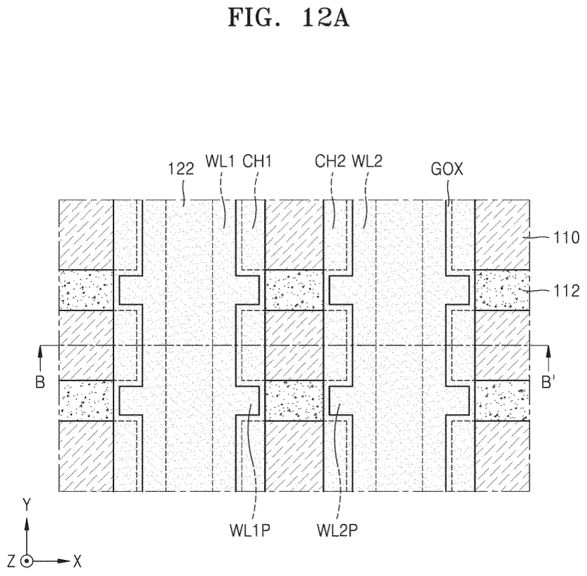

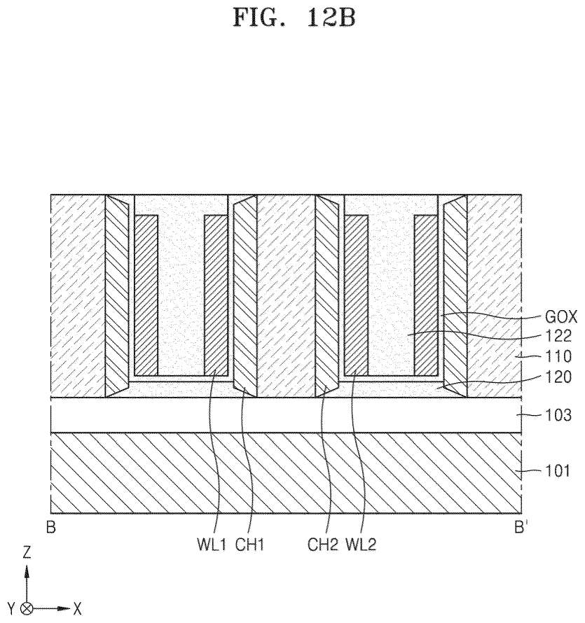

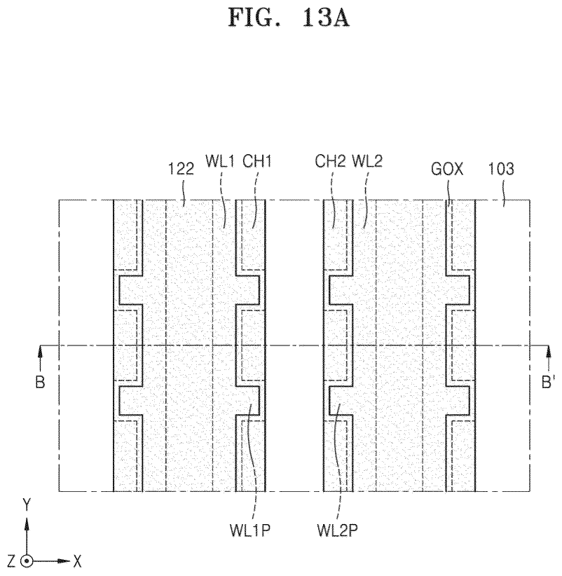

Referring to FIGS. 12A and 12B together, the second insulating pattern 122 may be formed to completely fill the inside of the first opening 110H (see FIG. 11B).

Accordingly, a level of a top surface of the second insulating pattern 122 may be substantially the same as a level of a top surface of the gate insulating pattern GOX.

Here, the second insulating pattern 122 may include the same material as the first insulating pattern 120. In addition, the second insulating pattern 122 may include a different material from the gate insulating pattern GOX. The second insulating pattern 122 may include, for example, a silicon oxide layer, a silicon oxynitride layer, or a silicon nitride layer. However, example embodiments are not limited thereto.

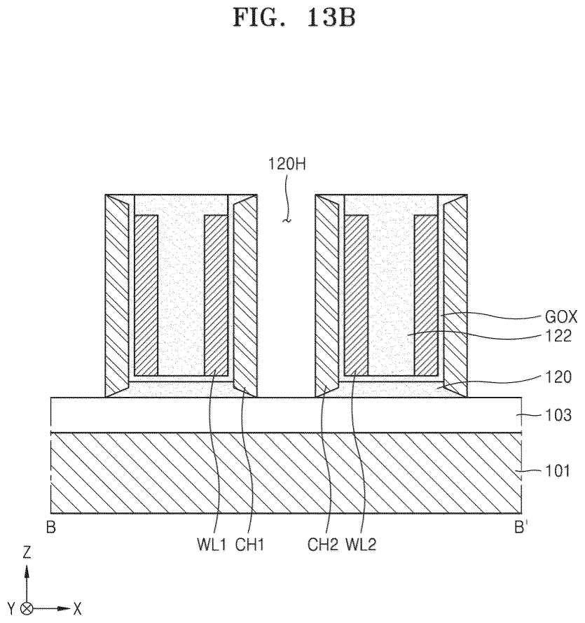

Referring to FIGS. 13A and 13B together, both the remaining sacrificial semiconductor layer 110 (see FIG. 12B) and the remaining sacrificial insulating layer 112 (see FIG. 12B) may be etched.

Etching may be performed using a wet etching process, but example embodiments are not limited thereto. Accordingly, second openings 120H extending in the second direction Y may be formed between the first and second vertical channel patterns CH1 and CH2. Through the second openings 120H, the top surface of the base insulating layer 103 may be exposed, and the sidewalls of the first and second vertical channel patterns CH1 and CH2 may be exposed. The second openings 120H may be spaced apart from each other by a certain distance in the first direction X.

Referring to FIGS. 14A and 14B together, the back gate insulating pattern 124 and the back gate electrode BG may be formed on the top surface of the base insulating layer 103 exposed by the second openings 120H (see FIG. 13B).

That is, according to the inventive concepts, the back gate electrode BG may be formed later than the first and second word lines WL1 and WL2 described above.

Bottom and side portions of the back gate insulating pattern 124 may be formed by forming an insulating material to completely fill the second openings 120H (see FIG. 13B) and then etching the insulating material by using an etching process. Next, the back gate electrode BG may be formed, and a top portion of the back gate insulating pattern 124 may be formed, so that the back gate insulating pattern 124 may be formed to surround the back gate electrode BG.

The back gate insulating pattern 124 may be used as an insulating pattern for height adjustment such that the position of the back gate electrode BG in the third direction Z is determined. That is, a vertical position of the back gate electrode BG may be adjusted according to a thickness of a bottom portion of the back gate insulating pattern 124. The back gate insulating pattern 124 may include, for example, a silicon oxide layer, a silicon oxynitride layer, or a silicon nitride layer.

Each of the back gate electrodes BG may be disposed between the first and second vertical channel patterns CH1 and CH2 that are adjacent to each other in the first direction X. In other words, the first vertical channel pattern CH1 may be disposed on one side of each of the back gate electrodes BG, and the second vertical channel pattern CH2 may be disposed on the other side thereof. The back gate electrode BG may include, for example, doped polysilicon, conductive metal nitride (e.g. titanium nitride and tantalum nitride), metal (e.g. tungsten, titanium, and tantalum), conductive metal silicide, conductive oxide, or a combination thereof. However, example embodiments are not limited thereto.

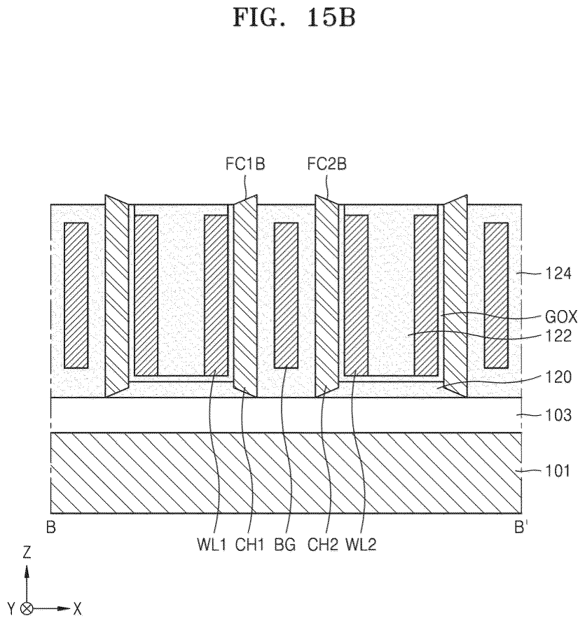

Referring to FIGS. 15A and 15B together, the top portion of each of the second insulating pattern 122, the gate insulating pattern GOX, and the back gate insulating pattern 124 may be etched so that the top portions of the first and second vertical channel patterns CH1 and CH2 are exposed.

Etching may be performed using a wet etching process, but example embodiments are not limited thereto. Accordingly, the inclined top portions of the first and second vertical channel patterns CH1 and CH2 may protrude to the outside. In other words, the first bottom facet FC1B of the first vertical channel pattern CH1 and the second bottom facet FC2B of the second vertical channel pattern CH2 may be exposed. Here, the above-described reference numerals are used as they are to avoid confusion of explanation, and accordingly, it will be easily understood by those skilled in the art that the reference numerals are referred to as the opposite of the top and bottom portions illustrated in the drawing.

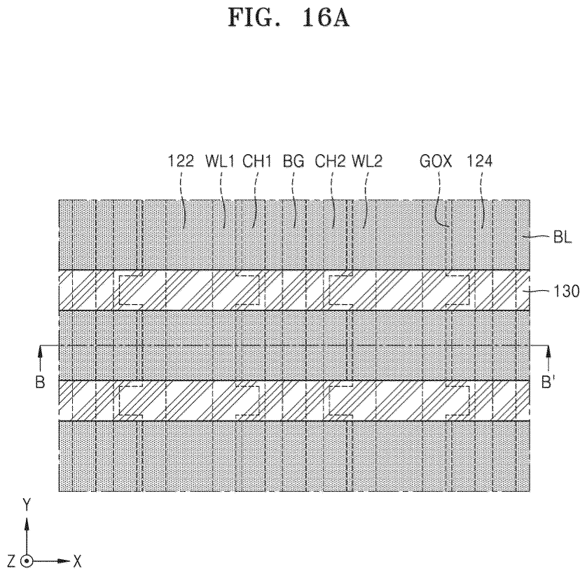

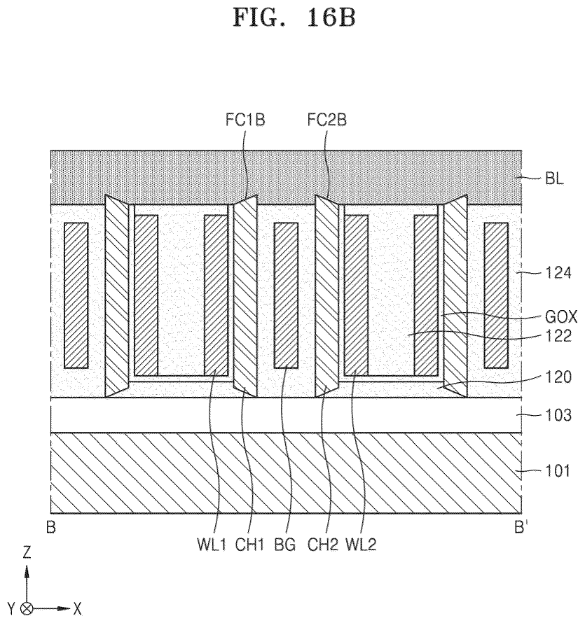

Referring to FIGS. 16A and 16B together, the bit lines BL covering the top portions of the first and second vertical channel patterns CH1 and CH2, and the insulating line layer 130 electrically insulating the bit lines BL may be formed.

The bit line BL may surround the top portions of the first and second vertical channel patterns CH1 and CH2 and extend in the first direction X on the second insulating pattern 122, the gate insulating pattern GOX, and the back gate insulating pattern 124. A plurality of bit lines BLs may extend in the first direction X and may be disposed to be spaced apart from each other in the second direction Y crossing the first direction X.

The bit line BL may include a conductive line. In some example embodiments, the bit line BL may include a conductive metal nitride (e.g., titanium nitride and tantalum nitride) or a metal (e.g., tungsten, titanium, and tantalum). Alternatively, the bit line BL may include metal silicide, such as titanium silicide, cobalt silicide, or nickel silicide. However, example embodiments are not limited thereto. Alternatively, the bit line BL may include doped polysilicon.

The insulating line layer 130 may include, for example, a silicon oxide layer, a silicon oxynitride layer, or a silicon nitride layer.

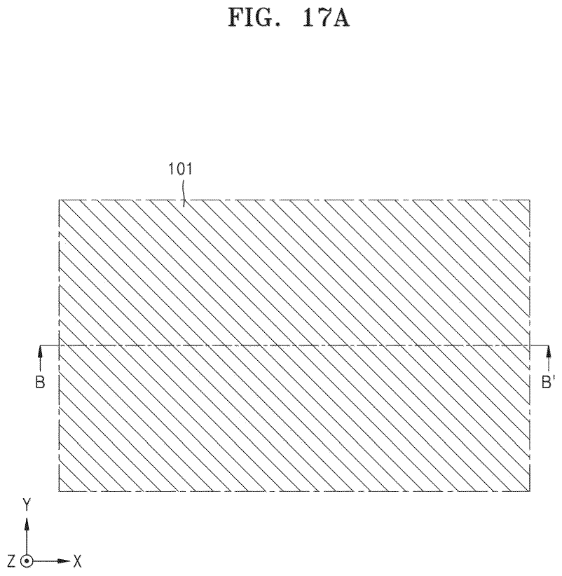

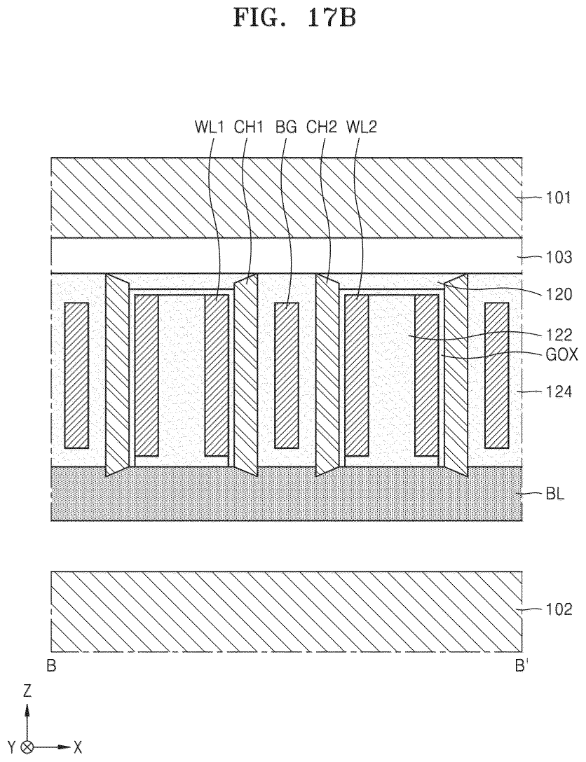

Referring to FIGS. 17A and 17B together, the first substrate 101 in which the back gate electrode BG, the first and second word lines WL1 and WL2, the first and second vertical channel patterns CH1 and CH2, and the bit line BL are formed may be turned over and aligned with the substrate 102.

Next, the bit line BL and the insulating line insulating layer 130 (see FIG. 16B) formed on the first substrate 101 and a top surface of the substrate 102 may be bonded to each other. Here, the substrate 102 may be referred to as a second substrate so as to be distinguished from the first substrate 101.

The substrate 102 may be one of a material (e.g., silicon and germanium) having semiconductor properties, an insulating material (e.g., glass and quartz), a semiconductor covered by the insulating material, or a conductor. However, example embodiments are not limited thereto. Here, the substrate 102 may be a wafer including silicon (Si).

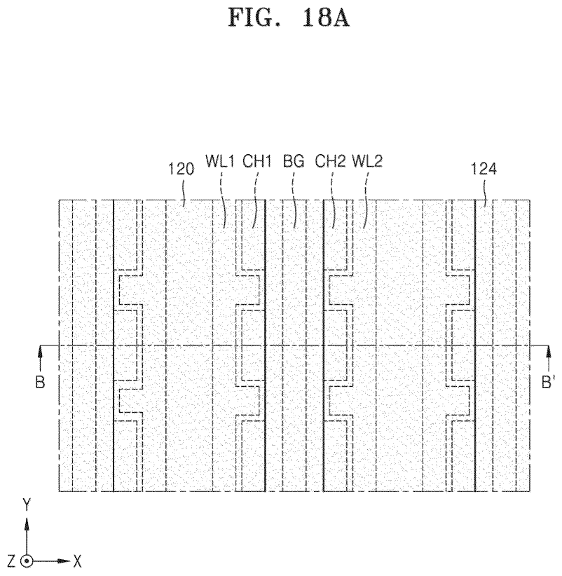

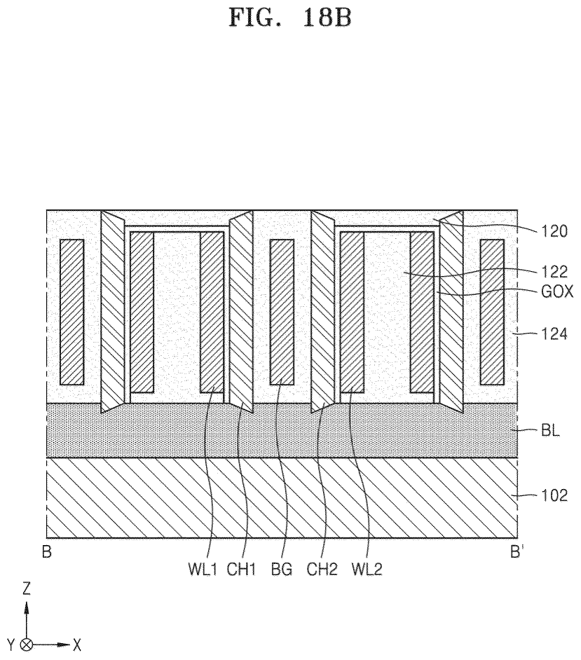

Referring to FIGS. 18A and 18B together, after bonding the substrate 102, a rear lapping process may be performed to remove the first substrate 101 (see FIG. 17B).

The process of removing the first substrate 101 (see FIG. 17B) may expose the first insulating pattern 120 and the back gate insulating pattern 124 by sequentially performing a grinding process and a wet etching process. At this time, the base insulating layer 103 (see FIG. 17B) formed on the first substrate 101 (see FIG. 17B) may also be removed.

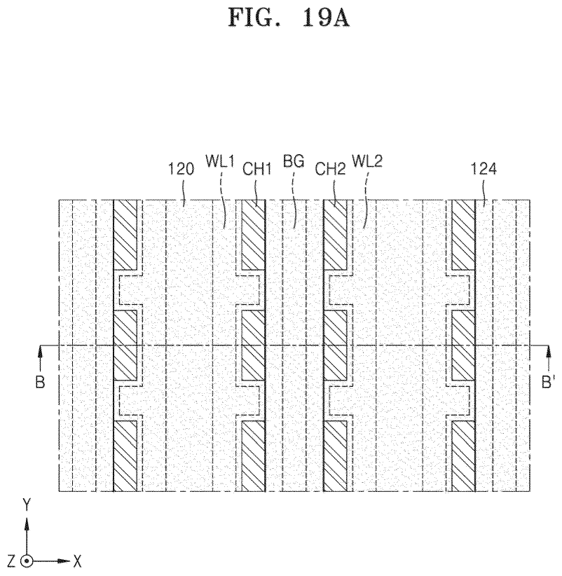

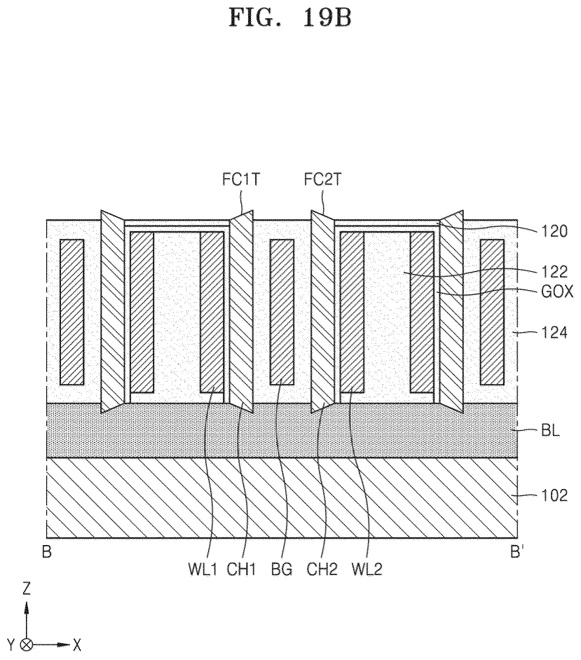

Referring to FIGS. 19A and 19B together, the top portion of each of the first insulating pattern 120 and the back gate insulating pattern 124 may be etched to expose the top portions of the first and second vertical channel patterns CH1 and CH2.

Etching may be performed using a wet etching process, but example embodiments are not limited thereto. Accordingly, the inclined top portions of the first and second vertical channel patterns CH1 and CH2 may protrude to the outside. In other words, the first top facet FC1T of the first vertical channel pattern CH1 and the second top facet FC2T of the second vertical channel pattern CH2 may be exposed.

Referring to FIGS. 20A and 20B together, the contact patterns BC covering the top portions of the first and second vertical channel patterns CH1 and CH2, and the isolation insulating layer 140 electrically insulating the contact patterns BC may be formed.

The contact pattern BC may surround the top portions of the first and second vertical channel patterns CH1 and CH2 and be formed in an island shape on the first insulating pattern 120 and the back gate insulating pattern 124. The contact patterns BC may be separated from each other by the isolation insulating layer 140. When viewed from a plan view, each of the contact patterns BC may have various shapes, such as circular, oval, rectangular, square, rhombic, or hexagonal shapes.

The contact pattern BC may include a conductive pattern. In some embodiments, the contact pattern BC may include a conductive metal nitride (e.g., titanium nitride and tantalum nitride) or a metal (e.g., tungsten, titanium, and tantalum). Alternatively, the bit line BL may include metal silicide, such as titanium silicide, cobalt silicide, or nickel silicide. However, example embodiments are not limited thereto. Alternatively, the contact pattern BC may include doped polysilicon.

The isolation insulating layer 140 may include, for example, a silicon oxide layer, a silicon oxynitride layer, or a silicon nitride layer. However, example embodiments are not limited thereto.

Referring again to FIGS. 1 and 2, the data storage pattern DSP may be formed on the contact pattern BC. Specifically, the storage electrodes 150 may be respectively formed on the contact patterns BC, and the capacitor dielectric layer 152 may be formed to conformally cover surfaces of the storage electrodes 150. Next, a plate electrode 154 may be formed on the capacitor dielectric layer 152. According to the manufacturing method, the semiconductor device 10 of the inventive concepts may be manufactured.

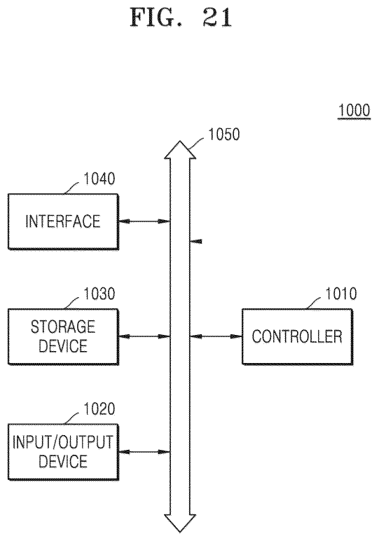

FIG. 21 is a configuration diagram illustrating a system 1000 including a semiconductor device according to an embodiment.

Referring to FIG. 21, system 1000 includes a controller 1010, an input/output device 1020, a storage device 1030, an interface 1040, and a bus 1050.

The system 1000 may be a mobile system or a system that transmits or receives information. In some embodiments, the mobile system may be a portable computer, a web tablet, a mobile phone, a digital music player, or a memory card.

The controller 1010 is for controlling an execution program in the system 1000 and may include a microprocessor, a digital signal processor, a microcontroller, or a similar device.

The input/output device 1020 may be used to input or output data of the system 1000. The system 1000 may be connected to an external device, for example, a personal computer or a network, by using the input/output device 1020, and may exchange data with the external device. The input/output device 1020 may be, for example, a touch screen, a touch pad, a keyboard, or a display.

The storage device 1030 may store data for the operation of the controller 1010 or store data processed by the controller 1010. The storage device 1030 may include the semiconductor device 10 according to the inventive concepts described above.

The interface 1040 may be a data transmission path between the system 1000 and the external device. The controller 1010, the input/output device 1020, the storage device 1030, and the interface 1040 may communicate with each other via the bus 1050.

Any of the elements disclosed above may include and/or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a substrate;
a bit line extending in a first direction on the substrate;
a first vertical channel pattern and a second vertical channel pattern on the bit line;
a back gate electrode between the first vertical channel pattern and the second vertical channel pattern and extending in a second direction perpendicular to the first direction across the bit line;
a first word line extending in the second direction from one side of the first vertical channel pattern;
a second word line extending in the second direction from other side of the second vertical channel pattern; and
a contact pattern connected to each of the first vertical channel pattern and the second vertical channel pattern,
wherein, when viewed from a cross-sectional view, each of the first vertical channel pattern and the second vertical channel pattern have a trapezoidal shape with the long sides facing each other.

2. The semiconductor device of claim 1, wherein each of the first vertical channel pattern and the second vertical channel pattern includes a silicon (Si) epitaxial growth layer.

3. The semiconductor device of claim 2, wherein
each of the first vertical channel pattern and the second vertical channel pattern has a top facet at a topmost portion of an inclined sidewall and a bottom facet at a bottommost portion of an inclined sidewall,
the first word line is faces a short side of the first vertical channel pattern without facing the top and bottom facets of the first vertical channel pattern, and
the second word line is faces a short side of the second vertical channel pattern without facing the top and bottom facets of the second vertical channel pattern.

4. The semiconductor device of claim 3, wherein the top facet of each of the first vertical channel pattern and the second vertical channel pattern contacts the contact pattern.

5. The semiconductor device of claim 3, wherein the bottom facet of each of the first vertical channel pattern and the second vertical channel pattern contacts the bit line.

6. The semiconductor device of claim 1, wherein, when viewed from a plan view,
the first word line has a plurality of first protrusions protruding between a plurality of the first vertical channel patterns, and
the second word line has a plurality of second protrusions protruding between a plurality of the second vertical channel patterns.

7. The semiconductor device of claim 6, wherein
the first word line and the plurality of first protrusions face the plurality of first vertical channel patterns on three different planes to form a tri-gate structure, and
the second word line and the plurality of second protrusions face the plurality of second vertical channel patterns on three different planes to form a tri-gate structure.

8. The semiconductor device of claim 6, wherein the plurality of first protrusions of the first word line and the plurality of second protrusions of the second word line have a mirror image symmetrical structure with respect to the back gate electrode.

9. The semiconductor device of claim 1, further comprising
a gate insulating pattern between the first and second word lines and the corresponding first and second vertical channel patterns,
wherein the gate insulating pattern extends to top surfaces of the first and second word lines.

10. The semiconductor device of claim 1, further comprising a data storage pattern connected to the contact pattern.

11. A semiconductor device comprising:
a substrate;
a bit line extending in a first direction on the substrate;
a pair of vertical channel patterns on the bit line;
a back gate electrode between the pair of vertical channel patterns and extending in a second direction perpendicular to the first direction across the bit line;
a pair of word lines outside the pair of vertical channel patterns and extending in the second direction; and
contact patterns connected to each of the pair of vertical channel patterns,
wherein each of the pair of vertical channel patterns is an epitaxially grown layer having a top facet at a topmost portion of an inclined sidewall and a bottom facet at a bottommost portion of an inclined sidewall.

12. The semiconductor device of claim 11, wherein the pair of vertical channel patterns have a mirror image symmetrical structure with respect to the back gate electrode.

13. The semiconductor device of claim 11, wherein, when viewed from a cross-sectional view,
each of the pair of vertical channel patterns has a trapezoidal shape,
the back gate electrode faces a long side of the trapezoidal shape, and
the pair of word lines face a short side of the trapezoidal shape.

14. The semiconductor device of claim 11, wherein
a level of a topmost surface of the pair of vertical channel patterns is higher than a level of a topmost surface of the pair of word lines, and
a level of a bottommost surface of the pair of vertical channel patterns is lower than a level of a bottommost surface of the pair of word lines.

15. The semiconductor device of claim 14, wherein
the level of a topmost surface of the pair of word lines is higher than a level of a topmost surface of the back gate electrode, and
the level of the bottommost surface of the pair of word lines is lower than a level of a bottommost surface of the back gate electrode.

16. A semiconductor device comprising:
a substrate;
a bit line extending in a first direction on the substrate;
a first vertical channel pattern and a second vertical channel pattern on the bit line;
a back gate electrode between the first and second vertical channel patterns and extending in a second direction perpendicular to the first direction across the bit line;
a first word line extending in the second direction from one side of the first vertical channel pattern;
a second word line extending in the second direction from other side of the second vertical channel pattern;
a gate insulating pattern conformally between the first and second vertical channel patterns and the first and second word lines and on top surfaces of the first and second word lines;
a contact pattern connected to each of the first vertical channel pattern and the second vertical channel pattern; and
a data storage pattern connected to the contact pattern,
wherein, when viewed from a cross-sectional view, each of the first vertical channel pattern and the second vertical channel pattern has a trapezoidal shape that is a mirror image symmetrical structure with respect to the back gate electrode.

17. The semiconductor device of claim 16, wherein
each of the first vertical channel pattern and the second vertical channel pattern has a top facet at a topmost portion of an inclined sidewall and a bottom facet at a bottommost portion of an inclined sidewall,
the top facet of each of the first vertical channel pattern and the second vertical channel pattern contacts the contact pattern, and
the bottom facet of each of the first vertical channel pattern and the second vertical channel pattern contacts the bit line.

18. The semiconductor device of claim 16, wherein, when viewed from a plan view,
the first word line has a plurality of first protrusions protruding between a plurality of the first vertical channel patterns, and
the second word line has a plurality of second protrusions protruding between a plurality of the second vertical channel patterns.

19. The semiconductor device of claim 18, wherein
the first word line and the plurality of first protrusions face the plurality of first vertical channel patterns on three different planes to form a tri-gate structure, and
the second word line and the plurality of second protrusions face the plurality of second vertical channel patterns on three different planes to form a tri-gate structure.

20. The semiconductor device of claim 19, wherein the plurality of first protrusions of the first word line and the plurality of second protrusions of the second word line have a mirror image symmetrical structure with respect to the back gate electrode.
